(19) United States
(12) Patent Application Publication
(10) Pub. No.: US 2008/0054484 A1
(43) Pub. Date: Mar. 6, 2008

(54) METHOD FOR PROTECTING AN ALIGNMENT MARK

(76) Inventor: Sang-Min Shim, Seoul (KR)

Correspondence Address: SHERR & NOURSE, PLLC, 620 HERNDON PARKWAY, SUITE 200, HERNDON, VA, 20170, US

(21) Appl. No.: 11/844,679

(22) Filed: Aug. 24, 2007

(30) Foreign Application Priority Data
Aug. 31, 2006 (KR) 10-2006-0083917

(51) Int. Cl. H01L 23/544; H01L 21/31; H01L 21/4763; H01L 23/48

(52) U.S. Cl. 257/774; 257/797; 438/637; 438/763; 257/E21.24; 257/E21.495; 257/E23.01; 257/E23.179

(57) ABSTRACT

A method for protecting an alignment mark on a semiconductor substrate, includes forming a dielectric layer on the semiconductor substrate having the alignment mark, forming a cap oxide film on the dielectric layer, wherein the cap oxide film is formed to have a regular thickness and an additional thickness, etching a portion of the dielectric layer and the cap oxide film to expose the semiconductor substrate to thereby form a via hole, filling the via hole with a metal, and performing a chemical mechanical polishing process with the metal and the cap oxide film to form a via contact.

The present application claims priority under 35 U.S.C. 119 to Korean Patent Application No. 10-2006-0083917 (filed on Aug. 31, 2006), which is hereby incorporated by reference in its entirety.

### BACKGROUND

In relatively highly integrated semiconductor devices, a planarization process (e.g. Chemical Mechanical Polishing (CMP)) may be important in Ultra Large Scale Integration (ULSI). Accordingly, alignment technology with relatively high reliability on a planarized wafer may be important in micro lithography.

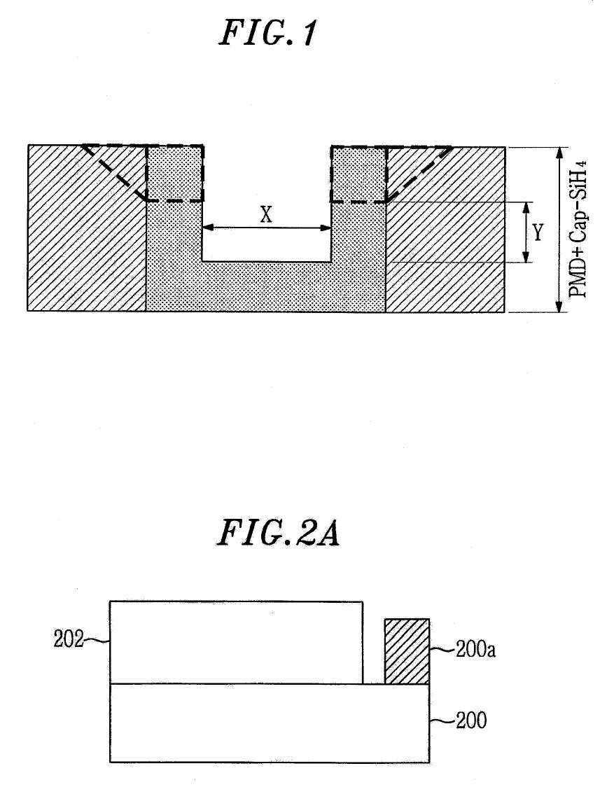

An alignment mark, as illustrated in example FIG. 1, may need to satisfy a minimum width (X) and step height (Y) for sensing in a lithography process. However, an alignment mark may not be able to be sensed if it has a step height smaller than a minimum step height, which may be due to dishing and/or erosion in a CMP process. Accordingly, in manufacturing processes (e.g. ULSI manufacturing processes), there is a need to sense, by an alignment sensor, an alignment mark having a very small step height on a wafer processed by CMP.

### SUMMARY

Embodiments relate to a method for protecting an alignment mark that minimizing damage to an alignment mark after a chemical mechanical polishing (CMP) process.

In embodiments, a method of protecting an alignment mark on a semiconductor substrate includes at least one of the following steps: Forming a dielectric layer on and/or over the semiconductor substrate having the alignment mark. Forming a cap oxide film on and/or over the dielectric layer, wherein the cap oxide film has a regular thickness and an additional thickness. Etching a portion of the dielectric layer and the cap oxide film to expose the semiconductor substrate to form a via hole. Filling the via hole with a metal. Performing a chemical mechanical polishing process with the metal and the cap oxide film to form a via contact.

### DRAWINGS

Example FIG. 1 illustrating an alignment mark.

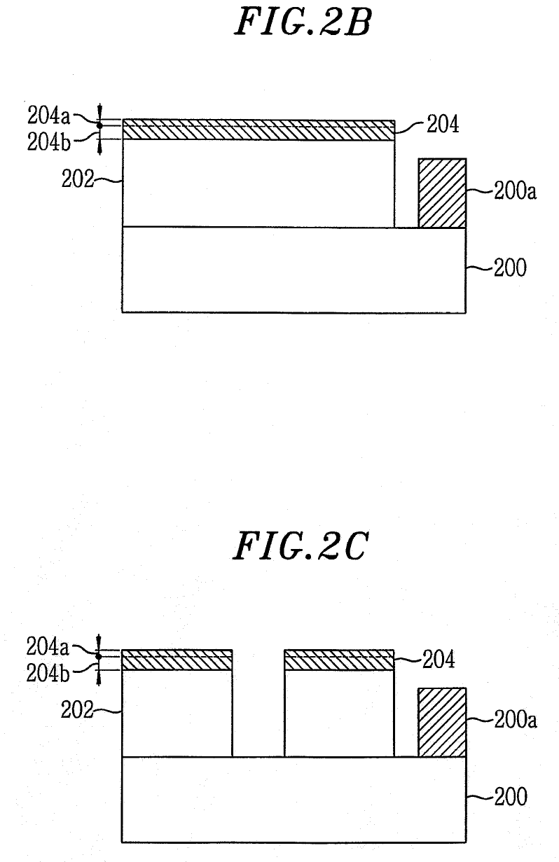

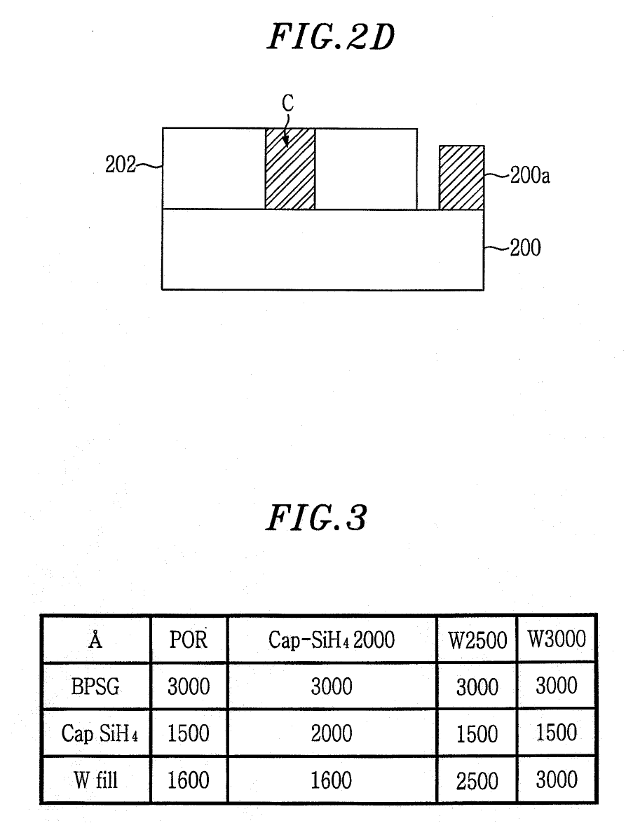

Example FIGS. 2A to 2D illustrate a procedure of protecting an alignment mark when forming a via contact, in accordance with embodiments.

Example FIG. 3 illustrates parameters of a metal layer, a dielectric layer, and a cap oxide film deposited over a semiconductor substrate, in accordance with embodiments.

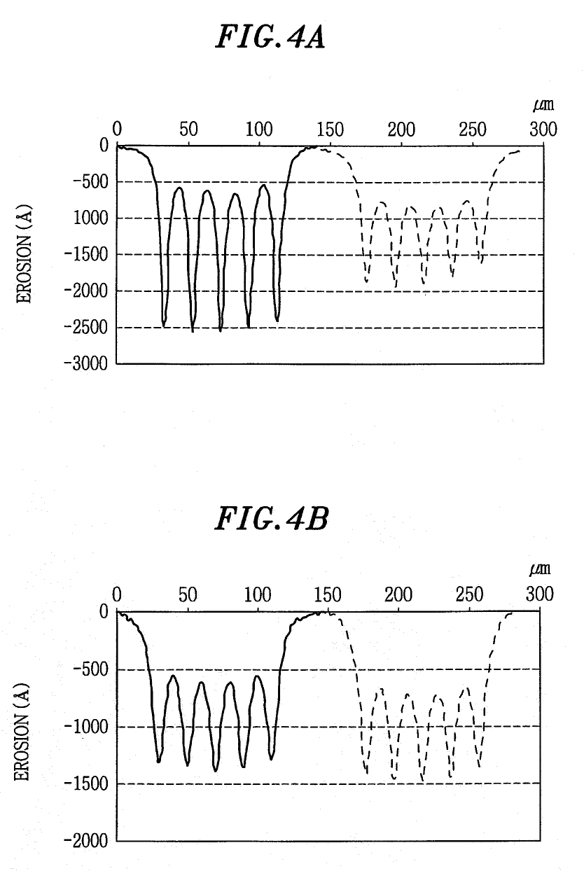

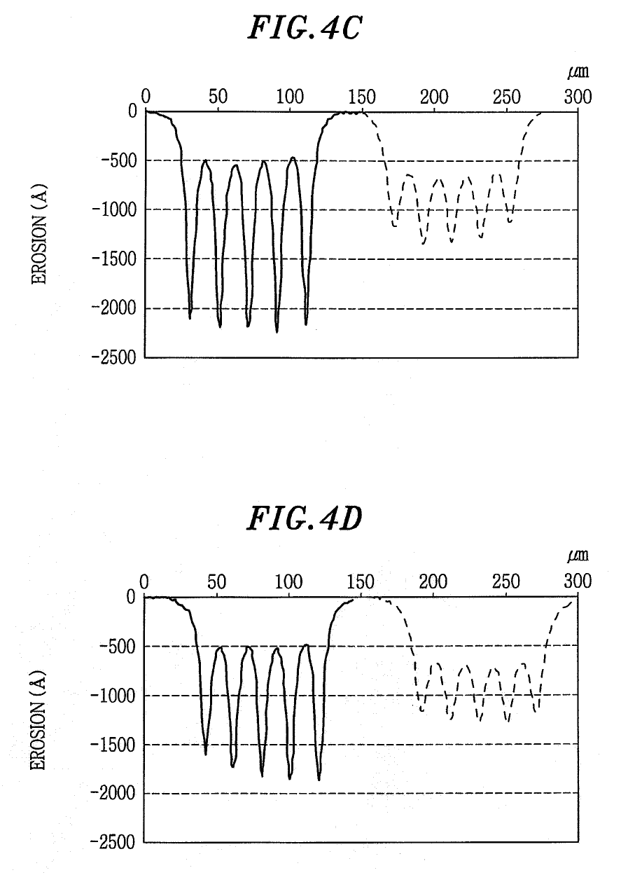

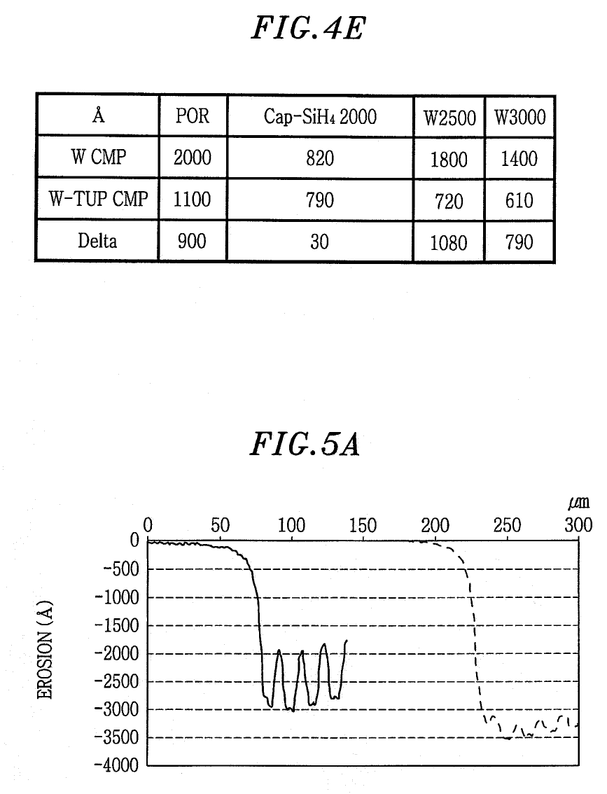

Example FIGS. 4A to 4E illustrating profiles for a Laser Step Alignment (LSA) mark, in accordance with embodiments.

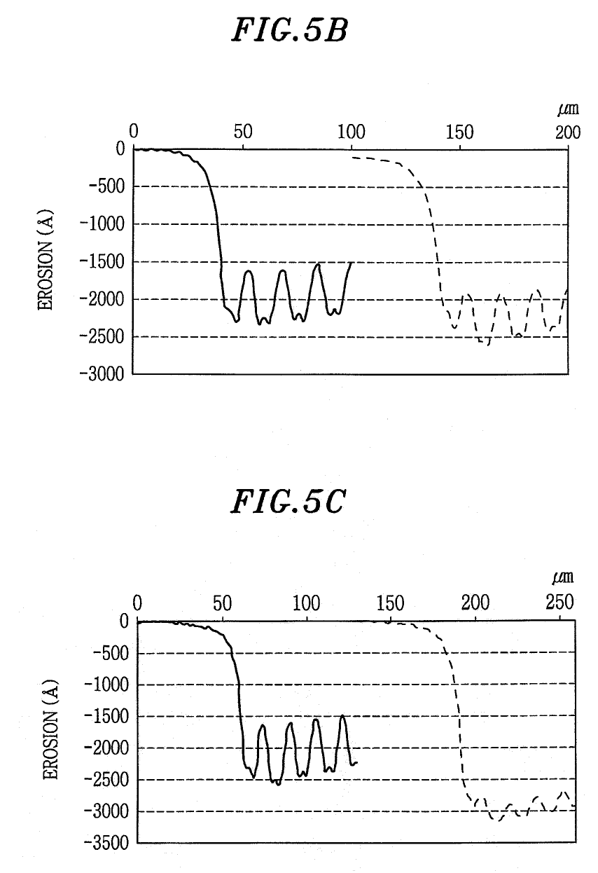

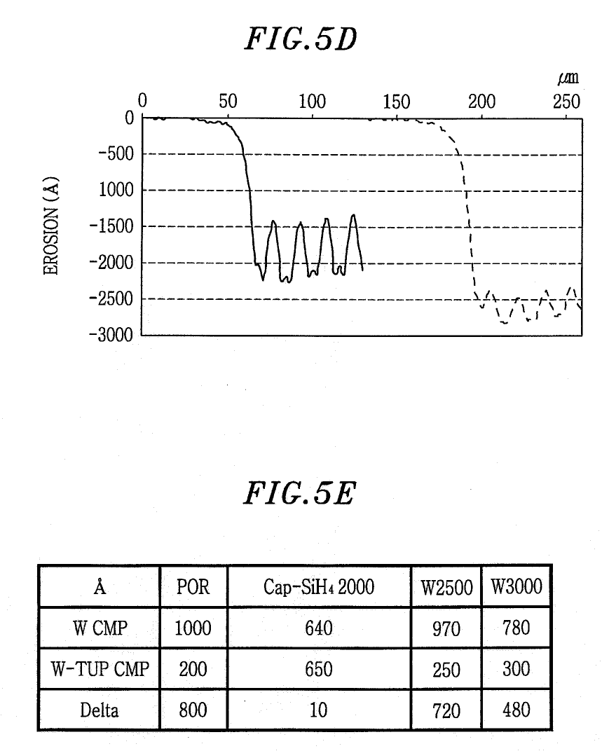

Example FIGS. 5A to 5E illustrate profiles for an ASML mark having a relatively large pattern density, in accordance with embodiments.

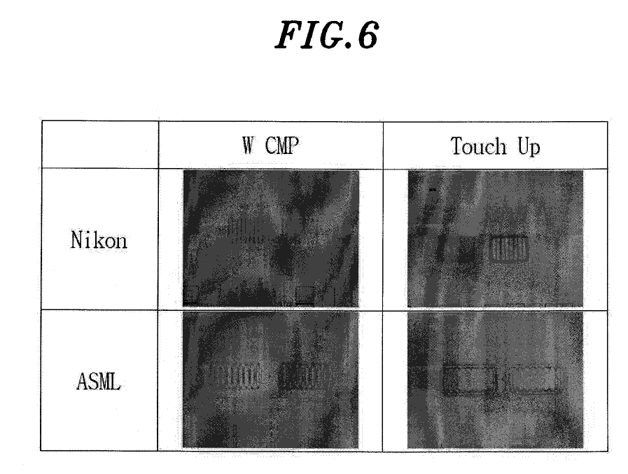

Example FIG. 6 illustrates a photograph of images of an LSA mark and an ASML mark after a main CMP and a touch up CMP are performed, in accordance with embodiments.

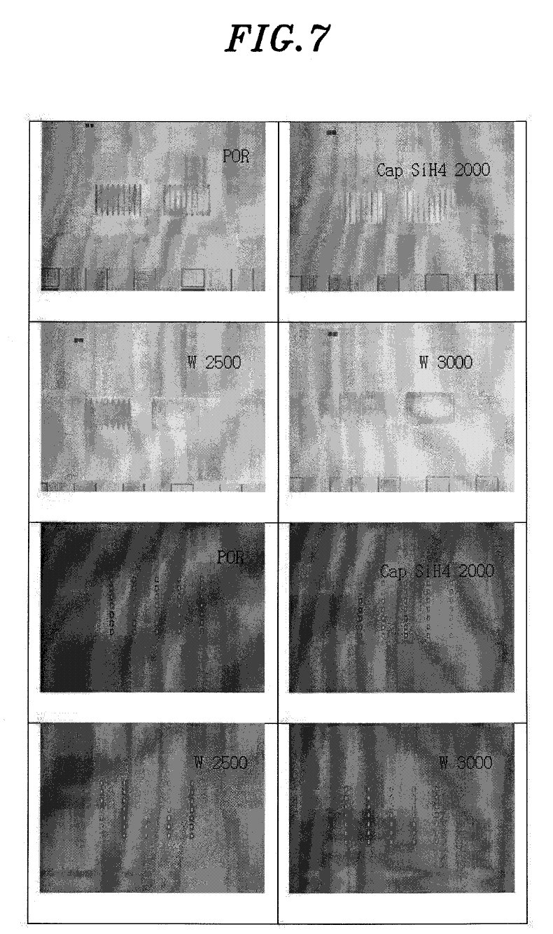

Example FIG. 7 illustrates a photograph of an image of a Field Image Alignment (FIA) mark, in accordance with embodiments.

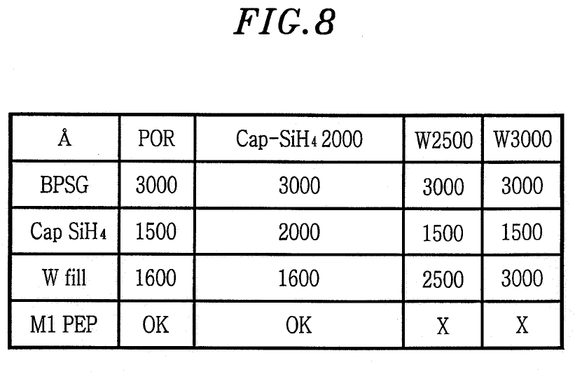

Example FIG. 8 illustrates an indication of a signal being sensed from an alignment mark in a lithography process, in accordance with embodiments.

### DESCRIPTION

Example FIGS. 2A to 2D are process cross-sectional diagrams illustrating a procedure for protecting an alignment mark when forming a via contact, in accordance with embodiments. As illustrated in example FIG. 2A, dielectric layer 202 (e.g. a BoroPhospho Silicate Glass (BPSG)) may be formed on and/or over semiconductor substrate 200, in accordance with embodiments. Dielectric layer 202 may be for forming a via contact. Semiconductor substrate 200 may include alignment mark 200a. Alignment mark 200a may include of a cap oxide film (SiH4) and/or a Pre-Metal Dielectric (PMD). A CMP process may be performed to planarize dielectric layer 202.

As illustrated in example to FIG. 2B, a cap oxide film 204 (e.g. SiH4) may be deposited on and/or over the planarized dielectric layer 202, in accordance with embodiments. In embodiments, cap oxide film 204 may have a regular thickness 204b and an additional thickness 204a. Regular thickness 204b may be a nominal height that is normally deposited when forming a cap oxide film during a semiconductor manufacturing process. Additional thickness 204a may be a supplementary height deposited in addition to the regular thickness 204b. For example, a regular thickness 204b of the cap oxide film 204 may be approximately 2000 Å on and/or over planarized dielectric layer 202, in accordance with embodiments. Additional thickness 204a may be between approximately 25% and approximately 35% of regular thickness 204b. The total thickness of cap oxide film 204 may be between approximately 2500 Å and approximately 2700 Å, in accordance with embodiments.

In embodiments, cap oxide film 204 (having a regular thickness and an additional thickness) may be formed by a single deposition. In embodiments, cap oxide film 204 may be formed by two depositions (e.g. one deposition for regular thickness 204b and one deposition for additional thickness 204a). Cap oxide film 204 may be formed relatively thick compared to a normal thickness of a cap oxide film by having additional thickness 204a, which may prevent damage to alignment mark 200a in a subsequent planarization process, in accordance with embodiments.

As illustrated in example FIG. 2C, dielectric layer 202 and cap oxide film 204 may be selectively etched to form a via hole, in accordance with embodiments. The via hole may be formed by coating and patterning a photoresist on and/or over cap oxide film 204. The patterned photoresist may be used as an etch mask in a photolithography process that forms the via hole.

As illustrated in example FIG. 2D, a metal layer (e.g. tungsten (W)) may be deposited to fill the via hole, in accordance with embodiments. A CMP process may be performed using dielectric layer 202 as a polishing stopper. A CMP process may remove a portion of the metal layer and cap oxide film 204 may be substantially completely removed to forming via contact C. A CMP process may include a main CMP process and a touch up CMP process. A main CMP process may polish the metal layer. A touch up CMP process may polish cap oxide film 204 and the metal layer.

There may be variations of a profile for alignment mark 200a depending on the thickness of the cap oxide film 204 and the parameters of a CMP process that forms via contact C. Example FIG. 3 illustrates conditions of dielectric layer 202, cap oxide film (SiH4) 204, and metal layer (W) deposited on and/over semiconductor substrate 200.

Example FIGS. 4A to 4D illustrate profiles of alignment marks 200a, in accordance with embodiments. In FIGS. 4A to 4D, the solid line classifies the thickness of the cap oxide film 204 after a main CMP process, based on the conditions illustrated in example FIG. 3, in accordance with embodiments. In FIGS. 4A to 4D, the dotted line classifies the thickness of cap oxide film 204 after a touch up CMP (‘TUP CMP’), based on the conditions illustrated in example FIG. 3, in accordance with embodiments. In embodiments, a LSA (laser step alignment) mark (e.g. available from NIKON Corporation, Japan) may be employed to form alignment mark 200a.

Example FIG. 4A illustrates a profile for a LSA mark with a process of reference (POR), in accordance with embodiments. Example FIG. 4B illustrates a profile of a LSA mark when the thickness of metal layer (W) is changed from approximately 1600 Å to approximately 2500 Å, in accordance with embodiments. Example FIG. 4C illustrates a profile of a LSA mark when the thickness of a cap oxide film (SiH4) is changed from approximately 1500 Å to approximately 2000 Å, in accordance with embodiments. Example FIG. 4D illustrates a profile of a LSA mark when the thickness of a metal layer (W) is changed from approximately 1600 Å to approximately 3000 Å, in accordance with embodiments. Example FIG. 4E illustrate a step height according to conditions illustrated in FIG. 3, in accordance with embodiments. In other words, FIG. 4E illustrates variations of the thickness of a POR, a cap oxide film (SiH4), and a metal layer (W) after a main CMP and a touch up CMP (‘TUP CMP’), including a difference (delta) between the thicknesses, in accordance with embodiments.

FIGS. 5A to 5E illustrate a profile of an ASML mark (e.g. available from ASML, Netherlands), in accordance with embodiments. An ASML may have a relatively large pattern density and may be used as alignment mark 200a. Example FIG. 5A illustrates a profile of an ASML mark with the process of reference (POR) of FIG. 3, in accordance with embodiments. Example FIG. 5B illustrates a profile of an ASML mark when the thickness of metal layer (W) is changed from approximately 1600 Å to approximately 2500 Å, in accordance with embodiments. Example FIG. 5C illustrates a profile of an ASML mark when the thickness of a cap oxide film (SiH4) is changed from approximately 1500 Å to approximately 2000 Å, in accordance with embodiments. Example FIG. 5D illustrates a profile of an ASML mark when the thickness of a metal layer (W) is changed from approximately 1600 Å to approximately 3000 Å, in accordance with embodiments. Example FIG. 5E illustrates variations thicknesses of a POR, a cap oxide film (SiH4), and a metal layer (W) after a main CMP (indicated by a solid line in FIGS. 5A through 5D) and a touch up CMP (‘TUP CMP’) (indicated by a dotted line in FIGS. 5A through 5D), including differences (delta) between thicknesses, in accordance with embodiments.

In embodiments illustrated in example FIGS. 5A to 5E, when an ASML mark is used as alignment mark 200a, a gap between pitches is relatively constant after a main CMP and a touch up CMP (‘TUP CMP’), when cap oxide film 202 is formed thicker by about 500 Å. An erosion thickness after a touch up CMP may be within a range of about 2000 Å to 3000 Å, which is greater by approximately three to four times than an LSA mark having a low pattern density.

Example FIG. 6 shows images of a LSA mark and a ASML mark after a main CMP and a touch up CMP, in accordance with embodiments. As illustrated in example FIG. 6, an ASML mark may have a relative large pattern density compared to an LSA mark, as shown by the ASML mark being more discolored than the LSA mark.

Example FIG. 7 shows an image of an FIA (field image alignment) mark (e.g. available from NIKON Corporation, Japan), under each condition after a touch up CMP, in accordance with embodiments. As illustrated in FIG. 7, when a thickness of a cap oxide film (SiH4) increases, an alignment mark is most distinct. When a thickness of the metal layer (W) increases, a difference between an alignment mark and a POR may be relatively small.

As illustrated in example FIG. 8, it may be checked whether a signal can be sensed from an alignment mark in an M1 PEP (lithography) process on a condition basis, in accordance with embodiments. In embodiments, a signal may be sensed from an alignment mark when a cap oxide film (SiH4) is greater than approximately 2000 Å. In embodiments, a signal may not be sensed from an alignment mark when a metal layer (W) has a relatively large thickness.

In embodiments, a cap oxide film may be formed relatively thick (e.g. by a predetermined additional thickness more than a regular thickness) prior to a CMP process. In embodiments, a relatively thick cap oxide film may minimize damage to an alignment mark during CMP, which may maximize semiconductor manufacturing yield.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a semiconductor substrate;
forming an alignment mark over the semiconductor substrate;
forming a dielectric layer over the semiconductor substrate; and
forming a cap oxide film over the dielectric layer, wherein the cap oxide film has a thickness configured to minimize degradation of the alignment mark during a planarization process.

2. The method of claim 1, wherein the method is a method for protecting the alignment mark formed over the semiconductor substrate.

3. The method of claim 1, wherein the cap oxide film has a regular thickness and an additional thickness.

4. The method of claim 3, wherein the regular thickness and the additional thickness are formed in a single deposition of the cap oxide film.

5. The method of claim 3, wherein the regular thickness is formed in a first deposition process and the additional thickness is formed in a second deposition process.

6. The method of claim 3, wherein the additional thickness has a thickness between approximately 25% and approximately 35% of the regular thickness.

7. The method of claim 1, wherein the thickness of the cap oxide film is approximately 2000 Å.

8. The method of claim 1, comprising etching a portion of the dielectric layer and the cap oxide film to expose the semiconductor substrate to form a via hole;
filling the via hole with a metal; and
chemical mechanical polishing the metal and the cap oxide film to form a via contact.

9. The method of claim 8, wherein said chemical mechanical polishing comprises:
a main chemical mechanical polishing to polish the metal; and
a touch-up mechanical polishing to polish the cap oxide layer.

10. The method of claim 8, wherein the chemical mechanical polishing process comprises removing part of the metal layer filled in the via hole and the cap oxide film, wherein the dielectric layer is a polishing stopper.

11. An apparatus comprising:
a semiconductor substrate;
an alignment mark formed over the semiconductor substrate;
a dielectric layer formed over the semiconductor substrate; and
a cap oxide film formed over the dielectric layer, wherein the cap oxide film has a thickness configured to minimize degradation of the alignment mark during a planarization process.

12. The apparatus of claim 11, wherein the apparatus is configured to protect the alignment mark formed over the semiconductor substrate.

13. The apparatus of claim 11, wherein the cap oxide film has a regular thickness and an additional thickness.

14. The apparatus of claim 13, wherein the regular thickness and the additional thickness are formed in a single deposition of the cap oxide film.

15. The apparatus of claim 13, wherein the regular thickness is formed in a first deposition process and the additional thickness is formed in a second deposition process.

16. The apparatus of claim 13, wherein the additional thickness has a thickness between approximately 25% and approximately 35% of the regular thickness.

17. The apparatus of claim 11, wherein the thickness of the cap oxide film is approximately 2000 Å.

18. The apparatus of claim 11, wherein:
a portion of the dielectric layer and the cap oxide film is etched to expose the semiconductor substrate to form a via hole;
the via hole is filled with a metal; and
the metal and the cap oxide film are chemically mechanically polished.

19. The apparatus of claim 18, wherein the metal and the cap oxide film are chemically mechanically polished by:
a main chemical mechanical polishing to polish the metal; and
a touch-up mechanical polishing to polish the cap oxide layer.

20. The apparatus of claim 18, wherein the metal and the cap oxide film are chemically mechanically polished by removing part of the metal layer filled in the via hole and the cap oxide film, wherein the dielectric layer is a polishing stopper.
